(19) United States
(12) Patent Application Publication
(10) Pub. No.: US 2026/0190351 A1
(43) Pub. Date: Jul. 2, 2026

(54) CONTACT STRUCTURE AND SEMICONDUCTOR MEMORY DEVICE INCLUDING THE SAME

(71) Applicant: Samsung Electronics Co., Ltd., Suwon-si (KR)

(72) Inventors: Taehyoung IM, Suwon-si (KR); Minkyu SUH, Suwon-si (KR); Gyeongho KANG, Suwon-si (KR); Sang-Kuk KIM, Suwon-si (KR); Hyunchul YOON, Suwon-si (KR); Jinkwan LEE, Suwon-si (KR)

(21) Appl. No.: 19/382,018

(22) Filed: Nov. 6, 2025

(30) Foreign Application Priority Data
Dec. 31, 2024 (KR) 10-2024-0202551

(51) Int. Cl. H10B 63/00

(52) U.S. Cl. CPC H10B 63/24

(57) ABSTRACT

A contact structure includes a contact insulation layer defining a preliminary contact hole, a first insulating spacer extending along a side of the preliminary contact hole, a second insulating spacer provided on an upper side surface of the first insulating spacer, and a contact filling a contact hole defined by the first insulating spacer and the second insulating spacer. Each of the contact provided on a bottom surface of the second insulating spacer and the contact provided on a side surface of the second insulating spacer has a width that increases in a direction from a bottom surface of the contact toward an upper surface thereof. A maximum width of the contact provided on the bottom surface of the second insulating spacer is greater than a minimum width of the contact provided on the side surface of the second insulating spacer.

### CROSS-REFERENCE TO RELATED APPLICATION(S)

The application claims benefit of priority under 35 U.S.C. § 119 to Korean Patent Application No. 10-2024-0202551, filed on Dec. 31, 2024, in the Korean Intellectual Property Office, the content of which is incorporated by reference herein in its entirety.

### TECHNICAL FIELD

The present disclosure relates generally to a contact structure and a semiconductor memory device.

### BACKGROUND

With the trend toward miniaturization and thinning of electronic products, there is an increasing demand for higher integration of memory devices. Cross-point memory devices have a structure in which upper electrodes and lower electrodes intersect vertically, with memory cells arranged in the intersecting regions. This structure results in small memory cells in a planar arrangement. Generally, memory cells in cross-point memory devices include a 2-terminal selector and a memory device connected in series with each other. As a result, the aspect ratio of a unit memory cell increases, thereby complicating the manufacturing process of memory cells and restricting the ability to increase the capacity of memory devices.

### SUMMARY

One or more example implementations provide a contact structure with improved electrical characteristics.

One or more example implementations provide a semiconductor memory device with improved electrical characteristics.

According to some implementations, a contact structure comprises a contact insulation layer defining a preliminary contact hole; a first insulating spacer extending along a side of the preliminary contact hole; a second insulating spacer provided on an upper side surface of the first insulating spacer; and a contact filling a contact hole defined by the first insulating spacer and the second insulating spacer. Each of the contact provided on a bottom surface of the second insulating spacer and the contact provided on a side surface of the second insulating spacer has a width that increases in a direction from a bottom surface of the contact toward an upper surface thereof. A maximum width of the contact provided on the bottom surface of the second insulating spacer is greater than a minimum width of the contact provided on the side surface of the second insulating spacer.

According to some implementations, a contact structure comprises a first conductive line extending in a first direction; a second conductive line extending in a second direction intersecting the first direction on the first conductive line; and a contact provided between the first conductive line and the second conductive line. The contact includes a first portion adjacent to the first conductive line and a second portion adjacent to the second conductive line. Each of the first portion and the second portion has a width that increases in a direction from the first conductive line toward the second conductive line. A maximum width of the first portion is greater than a minimum width of the second portion.

According to some implementations, a semiconductor memory device comprises a word line extending in a first direction; a bit line extending in a second direction intersecting the first direction and spaced apart from the word line in a third direction; a selector-only memory device provided between the word line and the bit line; and contacts electrically connected to the word line and the bit line, respectively. Each of the contacts includes a first portion relatively far from the word line or the bit line and a second portion relatively close to the word line or the bit line. Each of the first portion and the second portion has a width that increases along the third direction. A maximum width of the first portion is greater than a minimum width of the second portion.

Additional aspects will be set forth in part in the description which follows and, in part, will be apparent from the description, or may be learned by practice of the presented implementations.

### BRIEF DESCRIPTION OF DRAWINGS

The above and other aspects, features, and advantages of certain implementations of the present disclosure will be more apparent from the following description taken in conjunction with the accompanying drawings, in which:

FIG. 1 is a perspective view of a semiconductor memory device according to exemplary implementations.

FIG. 2 is a cross-sectional view of a contact structure according to exemplary implementations.

FIG. 3 is a flowchart illustrating a method of manufacturing a contact structure according to exemplary implementations.

FIGS. 4 to 13 are diagrams for explaining the method of manufacturing the contact structure of FIG. 3.

FIG. 14 is a cross-sectional view of a contact structure according to exemplary implementations.

FIG. 15 is a cross-sectional view of a contact structure according to exemplary implementations.

FIG. 16 is a cross-sectional view of a contact structure according to exemplary implementations.

FIG. 17 is a cross-sectional view of a contact structure according to exemplary implementations.

FIG. 18 is a cross-sectional view of a contact structure according to exemplary implementations.

FIG. 19 is a cross-sectional view of a contact structure according to exemplary implementations.

FIG. 20 is a cross-sectional view of a contact structure according to exemplary implementations.

FIG. 21 is a cross-sectional view of a contact structure according to exemplary implementations.

FIG. 22 is a cross-sectional view of a contact structure according to exemplary implementations.

### DETAILED DESCRIPTION

Hereinafter, example implementations are described in detail with reference to the accompanying drawings. Like components are denoted by like reference numerals throughout the specification, and repeated descriptions thereof are omitted. It will be understood that when an element or layer is referred to as being “on,” “connected to,” or “coupled to” another element or layer, it can be directly on, connected to, or coupled to the other element or layer, or intervening elements or layers may be present. By contrast, when an element is referred to as being “directly on,” “directly connected to” or “directly coupled to” another element or layer, or as “contacting” or “in contact with” another element (or using any form of the word “contact”), there are no intervening elements or layers present.

Implementations described herein are example implementations, and thus, the present disclosure is not limited thereto, and may be realized in various other forms. Each example implementation provided in the following description is not excluded from being associated with one or more features of another example or another example implementation also provided herein or not provided herein but consistent with the present disclosure. It will also be understood that, even if a certain step or operation of manufacturing an apparatus or structure is described later than another step or operation, the step or operation may be performed later than the other step or operation unless the other step or operation is described as being performed after the step or operation.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

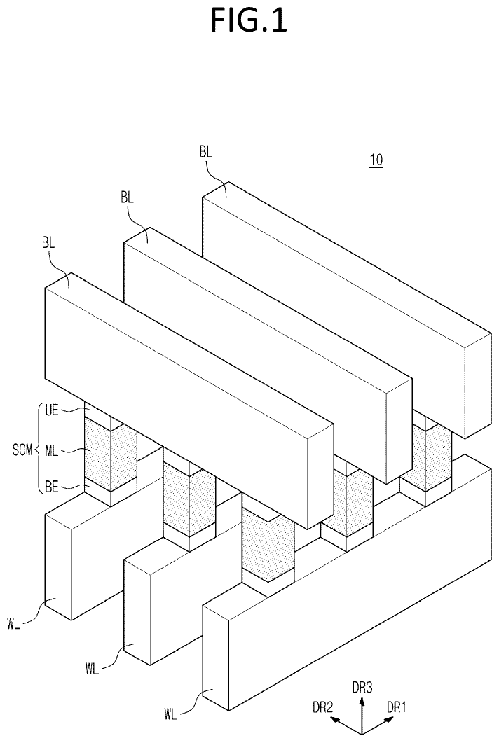

FIG. 1 is a perspective view of a semiconductor memory device according to exemplary implementations.

Referring to FIG. 1, a memory device 10 including word lines WL, bit lines BL, and selector-only memory devices SOM may be provided. The word lines WL may extend along a first direction DR1. The word lines WL may be arranged along a second direction DR2. The word lines WL may include an electrically conductive material. For example, the word lines WL may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs).

The bit lines BL may intersect the word lines WL. The bit lines BL may extend along the second direction DR2. In some implementations, the bit lines BL may be arranged along the first direction DR1, while the word lines WL may be arranged along the second direction DR2. The bit lines BL may include an electrically conductive material. For example, the bit lines BL may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs).

The selector-only memory devices SOM may be provided between the word lines WL and the bit lines BL. The selector-only memory devices SOM may be respectively disposed in regions where the word lines WL and the bit lines BL intersect.

Each of the selector-only memory devices SOM may include a bottom electrode BE, a memory layer ML, and an upper electrode UE arranged along a third direction DR3. The bottom electrode BE may be electrically connected to the word line WL. For example, the bottom electrode BE may contact the word line WL. The bottom electrode BE may include an electrically conductive material. For example, the bottom electrode BE may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs).

The upper electrode UE may be electrically connected to the bit line BL. For example, the upper electrode UE may contact the bit line BL. The upper electrode UE may include an electrically conductive material. For example, the upper electrode UE may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs).

The memory layer ML may have ovonic threshold switching (OTS) characteristics that have a high resistance state when a voltage lower than a threshold voltage (e.g., a voltage with a lower absolute value) is applied and a low resistance state when a voltage higher than the threshold voltage (e.g., a voltage with a higher absolute value) is applied. The memory layer ML may have memory characteristics in which the threshold voltage shifts according to the polarity and intensity of the applied bias voltage. Therefore, the memory layer ML may have characteristics of a self-selecting memory that can perform both memory function and selector function. In exemplary implementations, the memory layer ML may include a single material of a multi-component chalcogenide. For example, the memory layer ML may be a single layer including at least one material selected from GeAsSe, GeAsSeIn, GeAsSeSIn, GeAsSeSb, GeAsSeSbIn, GeAsSeTe, GeAsSeTeIn, GeAsSeAl, GeAsSeAlIn, GeSbSe, GeSbSeIn, GeSbSeN, and GeSbSeNIn.

For example, the memory layer ML may include a single layer such as indium In-doped GeAsSe. For example, the memory layer ML may include at least one material selected from GeAsSeIn, GeAsSeIn, and GeAsSeAlIn. For example, when the memory layer ML includes indium In doped or combined at an atomic concentration of about 10%, off-current leakage may increase. However, it can be experimentally confirmed that the resistance and threshold voltage drift characteristics of such indium-based devices can be significantly improved and the threshold voltage shift can be maintained at a similar value. In addition, in one implementation, the memory layer ML may not contain silicon Si. For example, when the memory layer ML does not include silicon Si, leakage current can be reduced to improve leakage current characteristics.

The word lines WL and the bit lines BL may be electrically connected to external conductive lines through contacts. The external lines may be configured to provide signals for storing data in the memory layer ML through the word lines WL and the bit lines BL, or to read data from the memory layer ML.

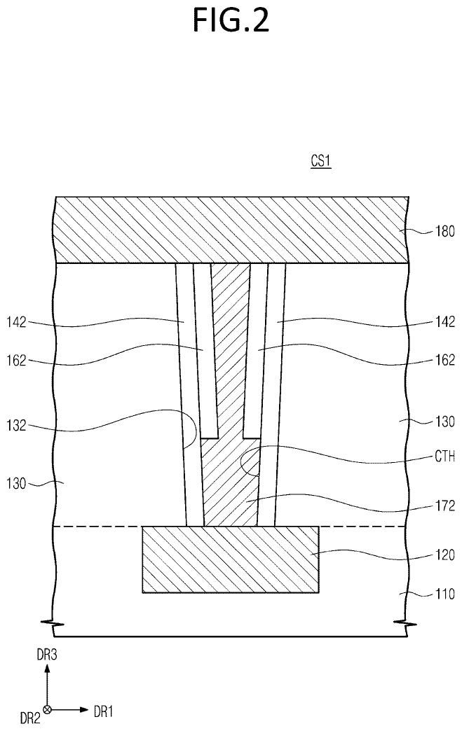

In exemplary implementations, the contacts may be configured to be connected to at least one of the ends of the corresponding bit lines BL along the second direction DR2 and at least one of the ends of the corresponding word lines WL along the first direction DR1. For example, the contacts may contact the bottom surface of the bit lines BL and the bottom surface of the word lines WL. For example, the external conductive lines may be provided at a lower level than the word lines WL. The bit line BL and the word line WL may correspond to the second conductive line 180 described later (FIG. 2). The external conductive line may correspond to the first conductive line 120 described later (FIG. 2).

Hereinafter, a contact configured to electrically connect a word line WL or a bit line BL to an external conductive line will be described.

FIG. 2 is a cross-sectional view of a contact structure according to exemplary implementations.

Referring to FIG. 2, a wiring insulation layer 110 may be provided. The wiring insulation layer 110 may include an electrical insulating material. For example, the wiring insulation layer 110 may include at least one of SiO₂, Al₂O₃, and HfO₂.

A first conductive line 120 may be buried in the upper portion of the wiring insulation layer 110. In exemplary implementations, the first conductive line 120 may be an external conductive line. The first conductive line 120 may extend along the second direction DR2. The first conductive line 120 may include an electrically conductive material. For example, the first conductive line 120 may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs).

A contact insulation layer 130 may be provided on the wiring insulation layer 110 and the first conductive line 120. The contact insulation layer 130 may include an electrical insulating material. For example, the contact insulation layer 130 may include at least one of SiO₂, Al₂O₃, and HfO₂. In exemplary implementations, the wiring insulation layer 110 and the contact insulation layer 130 may be connected to each other without an interface therebetween. In exemplary implementations, an interface may be provided between the wiring insulation layer 110 and the contact insulation layer 130.

The contact insulation layer 130 may include a preliminary contact hole 132. The preliminary contact hole 132 may extend along the third direction DR3. The preliminary contact hole 132 may penetrate the contact insulation layer 130. The preliminary contact hole 132 may expose the first conductive line 120. The contact insulation layer 130 adjacent to the preliminary contact hole 132 may cover the first conductive line 120.

A first insulating spacer 142 may be provided on the side of the contact insulation layer 130 exposed by the preliminary contact hole 132. A portion of the preliminary contact hole 132 may be filled by the first insulating spacer 142. For example, the first insulating spacer 142 may extend along the side of the contact insulation layer 130 exposed by the preliminary contact hole 132. The bottom of the first insulating spacer 142 may contact the first conductive line 120. The upper surface of the first insulating spacer 142 may be located at substantially the same level as the upper surface of the contact insulation layer 130. For example, the upper surface of the contact insulation layer 130 and the upper surface of the first insulating spacer 142 may be substantially coplanar. The first insulating spacer 142 may include an electrical insulating material. For example, the first insulating spacer 142 may include at least one of SiO₂, Al₂O₃, and HfO₂. An interface may be formed between the first insulating spacer 142 and the contact insulation layer 130.

A second insulating spacer 162 may be provided on the side of the first insulating spacer 142 facing the inside of the preliminary contact hole 132. Another portion of the preliminary contact hole 132 may be filled by the second insulating spacer 162. The remaining portion of the preliminary contact hole 132 may be referred to as a contact hole CTH. The second insulating spacer 162 may be provided on the upper portion of the first insulating spacer 142. The upper surface of the second insulating spacer 162 may be located at substantially the same level as the upper surface of the first insulating spacer 142. For example, the upper surface of the second insulating spacer 162 and the upper surface of the first insulating spacer 142 may be substantially coplanar. The bottom of the second insulating spacer 162 may be spaced apart from the first conductive line 120. The lower portion of the first insulating spacer 142 may be exposed, at the bottom surface of the second insulating spacer 162 i.e., the lower portion of the first insulating spacer 142 is free of the second insulating spacer 162. The second insulating spacer 162 may include an electrical insulating material. For example, the second insulating spacer 162 may include at least one of SiO₂, Al₂O₃, and HfO₂. An interface may be formed between the first insulating spacer 142 and the second insulating spacer 162.

A contact 172 may be provided in the contact hole CTH. The contact 172 may fill the contact hole CTH. The contact 172 may be electrically connected to the first conductive line 120. For example, the contact 172 may directly contact the first conductive line 120. The contact 172 may include an electrically conductive material. For example, the contact 172 may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs).

The contact 172 may contact the side and bottom surface of the second insulating spacer 162. The contact 172 may contact the side of the first insulating spacer 142 exposed at the bottom surface of the second insulating spacer 162. The contact 172 may have a width that increases, then narrows, and then increases again along the third direction DR3. For example, the width of the contact 172 may be the size of the contact 172 along the first direction DR1. The width of the contact 172 provided between the second insulating spacer 162 and the first conductive line 120 may increase along the third direction DR3. The width of the contact 172 provided on the side of the second insulating spacer 162 may increase along the third direction DR3. The maximum width of the contact 172 provided between the second insulating spacer 162 and the first conductive line 120 may be greater than the maximum width of the contact 172 provided on the side of the second insulating spacer 162. The minimum width of the contact 172 provided between the second insulating spacer 162 and the first conductive line 120 may be greater than the maximum width of the contact 172 provided on the side of the second insulating spacer 162.

A second conductive line 180 may be provided on the contact 172. In exemplary implementations, the second conductive line 180 may be a word line WL or a bit line BL. Exemplarily, the second conductive line 180 is illustrated as a word line WL extending along the first direction DR1. When the second conductive line 180 is a bit line BL, the second conductive line 180 may extend along the second direction DR2. The second conductive line 180 may be electrically connected to the contact 172. For example, the second conductive line 180 may directly contact the contact 172. The second conductive line 180 may include an electrically conductive material. For example, the second conductive line 180 may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs).

The contact 172 of the present disclosure may have an upper portion with a small width and a lower portion with a large width. The contact 172 may be electrically connected to the word line or the bit line at the upper portion. The small upper width of the contact 172 may reduce or substantially prevent undesired electrical influence from adjacent word lines or adjacent bit lines. The large lower width of the contact 172 may widen the area of the contact 172 that contacts the external conductive line. Accordingly, the contact 172 may be easily electrically connected to the external conductive line. Therefore, a contact structure CS1 and a semiconductor memory device 10 with improved electrical characteristics may be provided.

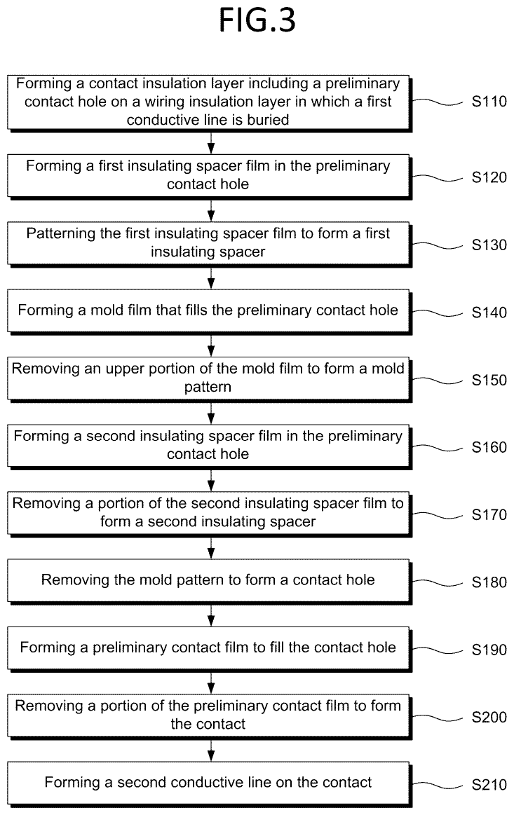

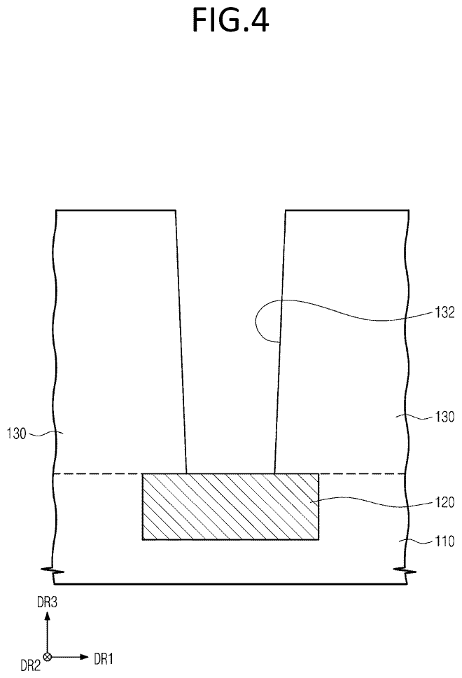

FIG. 3 is a flowchart illustrating a method of manufacturing a contact structure according to exemplary implementations. FIGS. 4 to 13 are diagrams for explaining the method of manufacturing the contact structure of FIG. 3.

Referring to FIGS. 3 and 4, a contact insulation layer 130 including a preliminary contact hole 132 may be formed on a wiring insulation layer 110 in which a first conductive line 120 is buried (S110). Burying the first conductive line 120 in the wiring insulation layer 110 may include forming a portion of the wiring insulation layer 110, forming the first conductive line 120 extending along the second direction DR2 on a portion of the wiring insulation layer 110, and forming another portion of the wiring insulation layer 110 on the side of the first conductive line 120. For example, forming the portion and the other portion of the wiring insulation layer 110 may be performed by a chemical vapor deposition process or a physical vapor deposition process. The wiring insulation layer 110 may include an electrical insulating material. For example, the wiring insulation layer 110 may include at least one of SiO₂, Al₂O₃, and HfO₂.

Forming the first conductive line 120 may include, for example, forming a conductive film on the portion of the wiring insulation layer 110 and patterning the conductive film. For example, forming the conductive film may be performed by a chemical vapor deposition process or a physical vapor deposition process. The conductive film may include an electrically conductive material. For example, the conductive film may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs). For example, the conductive film may be patterned by a dry etching process or a wet etching process using an etching mask provided on the conductive film.

Forming the contact insulation layer 130 including the preliminary contact hole 132 may include forming the contact insulation layer 130 on the wiring insulation layer 110 and the first conductive line 120 and patterning the contact insulation layer 130. For example, forming the contact insulation layer 130 may be performed by a chemical vapor deposition process or a physical vapor deposition process. The contact insulation layer 130 may include an electrical insulating material. For example, the contact insulation layer 130 may include at least one of SiO₂, Al₂O₃, and HfO₂. In exemplary implementations, the wiring insulation layer 110 and the contact insulation layer 130 may be connected to each other without an interface therebetween. In exemplary implementations, an interface may be provided between the wiring insulation layer 110 and the contact insulation layer 130. For example, the contact insulation layer 130 may be patterned by a dry etching process or a wet etching process using an etching mask provided on the contact insulation layer 130. Patterning the contact insulation layer 130 may be performed until the first conductive line 120 is exposed.

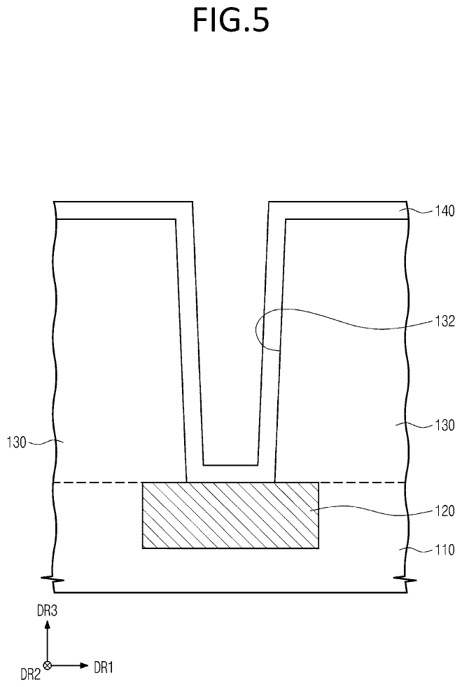

Referring to FIGS. 3 and 5, a first insulating spacer film 140 may be formed in the preliminary contact hole 132. The first insulating spacer film 140 may extend along the side and bottom surface of the contact hole CTH. The first insulating spacer film 140 may be provided on the side of the contact insulation layer 130 exposed by the preliminary contact hole 132 and on the upper surface of the first conductive line 120. The first insulating spacer film 140 may be provided on the upper surface of the contact insulation layer 130. The first insulating spacer film 140 may include an electrical insulating material. For example, the first insulating spacer film 140 may include at least one of SiO₂, Al₂O₃, and HfO₂.

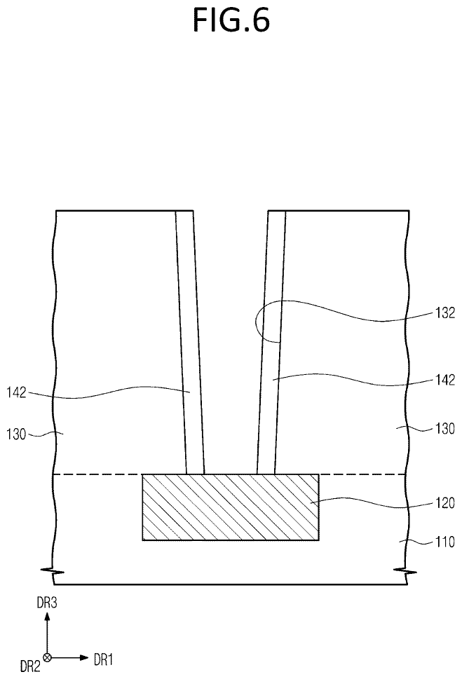

Referring to FIGS. 3 and 6, a portion of the first insulating spacer film 140 may be removed to form the first insulating spacer 142 (S130). Removing a portion of the first insulating spacer film 140 may include, for example, an etch-back process on the first insulating spacer film 140. The etch-back process may be performed until the upper surface of the contact insulation layer 130 and the upper surface of the first conductive line 120 are exposed. The first insulating spacer 142 may be provided on the side of the contact insulation layer 130 exposed by the preliminary contact hole 132. A portion of the preliminary contact hole 132 may be filled by the first insulating spacer 142. The upper surface of the first insulating spacer 142 may be located at substantially the same level as the upper surface of the contact insulation layer. For example, the upper surface of the contact insulation layer 130 and the upper surface of the first insulating spacer 142 may be substantially coplanar.

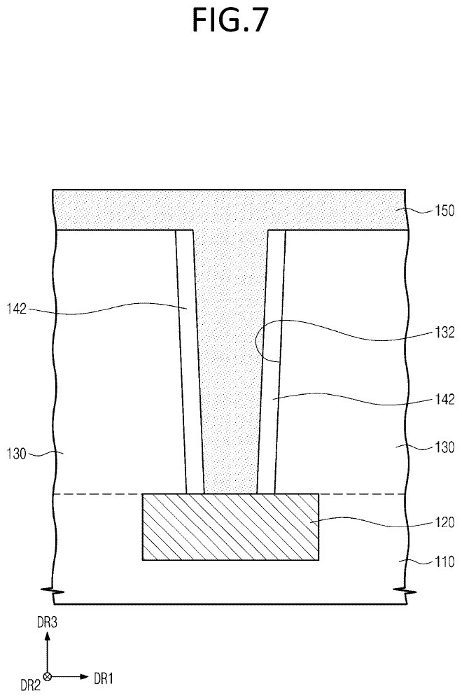

Referring to FIGS. 3 and 7, a mold film 150 may be formed to fill the remaining portion of the preliminary contact hole 132 (S140). The mold film 150 may further be provided on the upper surface of the contact insulation layer 130 to cover the upper surface of the contact insulation layer 130. For example, the mold film 150 may include a spin-on hard mask. For example, forming the mold film 150 may include spin coating a spin-on hard mask on the contact insulation layer 130 and curing the spin-on hard mask.

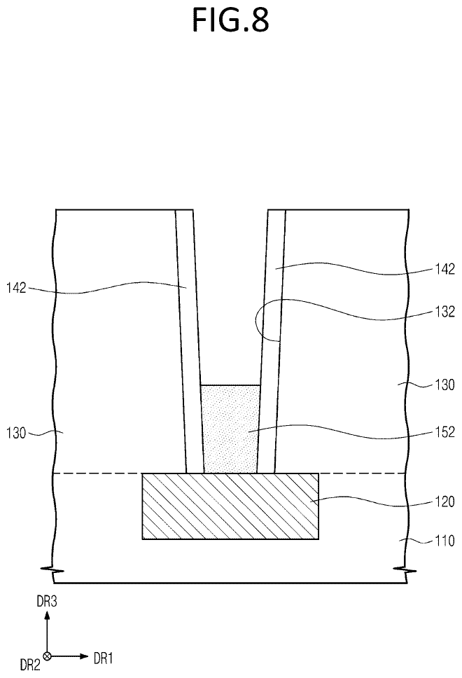

Referring to FIGS. 3 and 8, an upper portion of the mold film 150 may be removed to form a mold pattern 152 (S150). For example, removing the upper portion of the mold film 150 may include an ashing process using oxygen plasma. The mold pattern 152 may be provided in the lower portion of the preliminary contact hole 132. The mold pattern 152 may contact the upper surface of the first conductive line 120 and the side of the first insulating spacer 142 adjacent to the first conductive line 120. When the upper portion of the mold film 150 is removed, the upper side of the first insulating spacer 142 may be exposed.

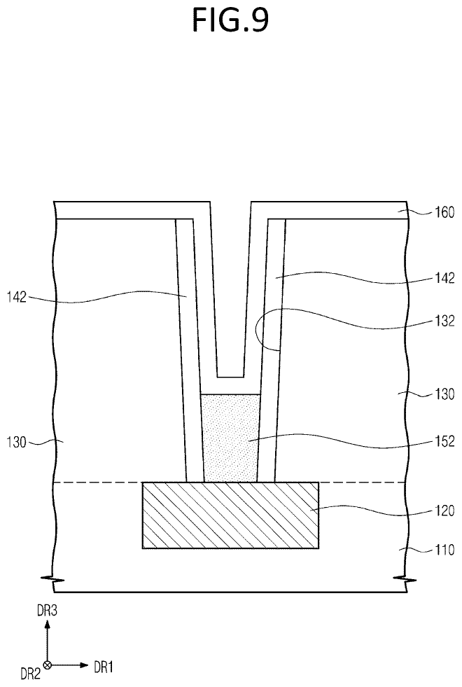

Referring to FIGS. 3 and 9, a second insulating spacer film 160 may be formed in the preliminary contact hole 132 (S160). The second insulating spacer film 160 may extend along the side and bottom surface of the preliminary contact hole 132 in which the first insulating spacer 142 and the mold pattern 152 are formed. The second insulating spacer film 160 may be provided on the side of the first insulating spacer 142 and on the upper surface of the mold pattern 152. The second insulating spacer film 160 may be provided on the upper surface of the first insulating spacer 142 and the upper surface of the contact insulation layer 130. The second insulating spacer film 160 may include an electrical insulating material. For example, the second insulating spacer film 160 may include at least one of SiO₂, Al₂O₃, and HfO₂.

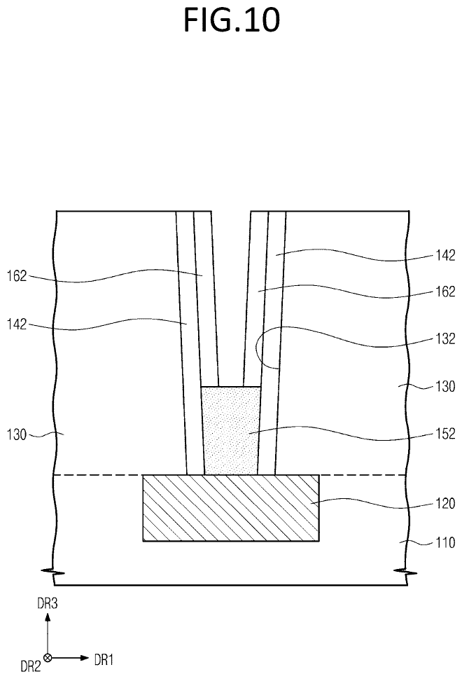

Referring to FIGS. 3 and 10, a portion of the second insulating spacer film 160 may be removed to form the second insulating spacer 162 (S170). Removing a portion of the second insulating spacer film 160 may include, for example, an etch-back process on the second insulating spacer film 160. The etch-back process may be performed until the upper surface of the contact insulation layer 130 and the upper surface of the mold pattern 152 are exposed. The second insulating spacer 162 may be formed on the side of the first insulating spacer 142. Another portion of the preliminary contact hole 132 may be filled by the second insulating spacer 162. The upper surface of the second insulating spacer 162 may be located at substantially the same level as the upper surface of the first insulating spacer 142. For example, the upper surface of the second insulating spacer 162 and the upper surface of the first insulating spacer 142 may be substantially coplanar.

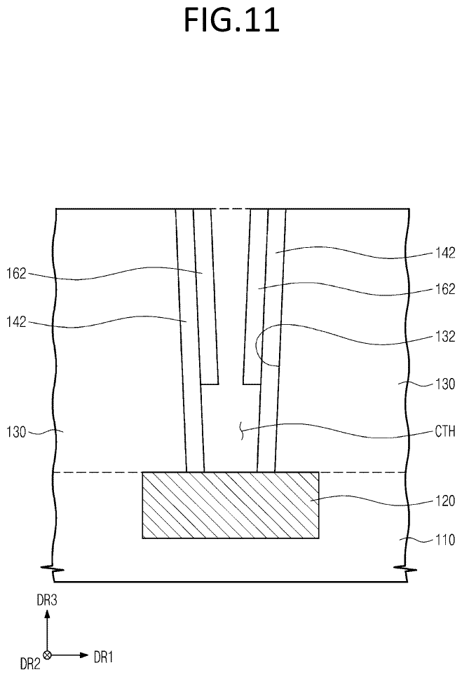

Referring to FIGS. 3 and 11, the mold pattern 152 may be removed to form a contact hole CTH (S180). For example, removing the mold pattern 152 may include an ashing process using oxygen plasma. The contact hole CTH may be a region between the first insulating spacer 142 and the second insulating spacer 162 in the preliminary contact hole 132. The contact hole CTH may expose the bottom surface of the second insulating spacer 162, the lower side of the first insulating spacer 142 on the bottom surface of the second insulating spacer 162, and the upper surface of the first conductive line 120.

The contact hole CTH may have a width that increases, then narrows, and then increases again along the third direction DR3. For example, the width of the contact hole CTH may be the size of the contact hole CTH along the first direction DR1. The width of the contact hole CTH provided between the second insulating spacer 162 and the first conductive line 120 may increase along the third direction DR3. The width of the contact hole CTH provided on the side of the second insulating spacer 162 may increase along the third direction DR3. The maximum width of the contact hole CTH provided between the second insulating spacer 162 and the first conductive line 120 may be greater than the maximum width of the contact hole CTH provided on the side of the second insulating spacer 162.

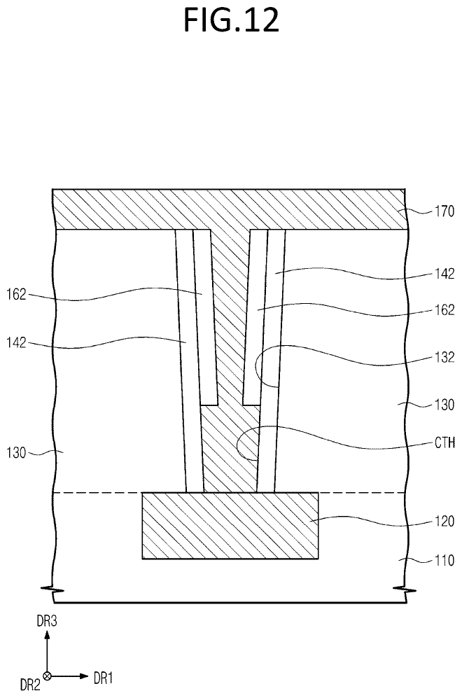

Referring to FIGS. 3 and 12, a preliminary contact film 170 may be formed to fill the contact hole CTH (S190). The preliminary contact film 170 may further be provided on the upper surface of the contact insulation layer 130 to cover the upper surface of the contact insulation layer 130. For example, the preliminary contact film 170 may include an electrically conductive material. For example, the preliminary contact film 170 may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs).

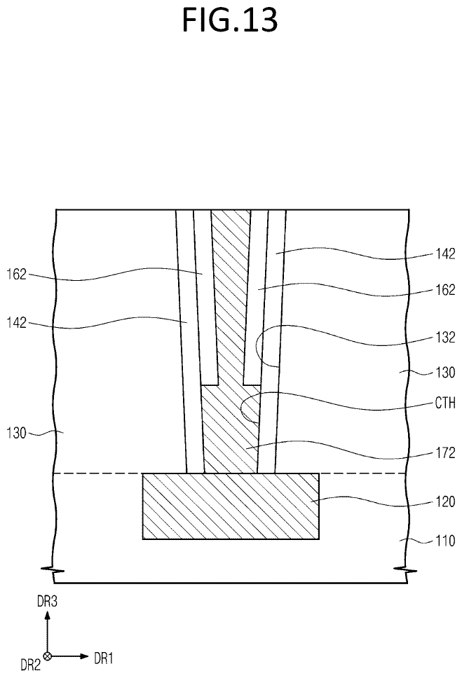

Referring to FIGS. 3 and 13, a portion of the preliminary contact film 170 may be removed to form the contact 172 (S200). Removing a portion of the preliminary contact film 170 may include, for example, an etch-back process on the preliminary contact film 170. The etch-back process may be performed until the upper surface of the contact insulation layer 130, the upper surface of the first insulating spacer 142, and the upper surface of the second insulating spacer 162 are exposed. The contact 172 may fill the contact hole CTH. The upper surface of the contact 172 may be located at substantially the same level as the upper surface of the second insulating spacer 162. For example, the upper surface of the contact 172 and the upper surface of the second insulating spacer 162 may be substantially coplanar.

Referring to FIGS. 3 and 2, a second conductive line 180 may be formed on the contact 172 (S210). Forming the second conductive line 180 may include, for example, forming a conductive film on the contact insulation layer 130 and patterning the conductive film. For example, forming the conductive film may be performed by a chemical vapor deposition process or a physical vapor deposition process. The conductive film may include an electrically conductive material. For example, the conductive film may include at least one of a metal (e.g., titanium Ti, titanium nitride TiN, tungsten W, platinum Pt, tantalum nitride TaN, aluminum Al) and a doped semiconductor material (e.g., doped Si, doped IGZO, doped GaAs). For example, the conductive film may be patterned by a dry etching process or a wet etching process using an etching mask provided on the conductive film.

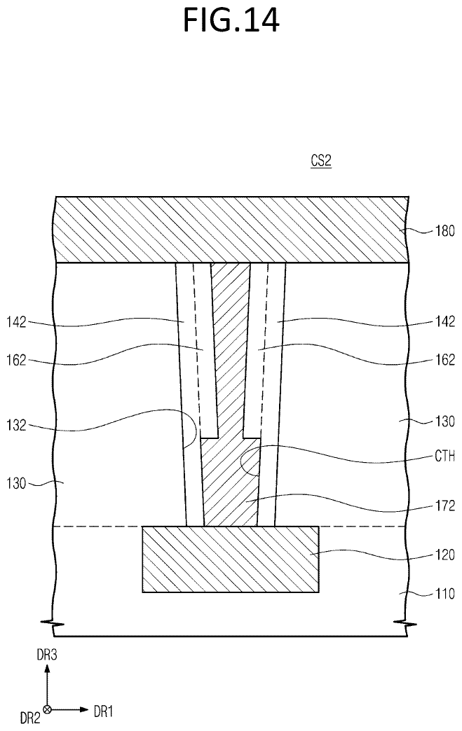

FIG. 14 is a cross-sectional view of a contact structure according to exemplary implementations. For the sake of brevity, differences from what was described with reference to FIG. 2 are described.

Referring to FIG. 14, a contact structure CS2 may be provided. Unlike what was described with reference to FIG. 2, the first insulating spacer 142 and the second insulating spacer 162 may constitute a single film. The first insulating spacer 142 and the second insulating spacer 162 may be connected to each other without an interface therebetween. For example, the first insulating spacer 142 and the second insulating spacer 162 may include substantially the same material. For convenience of explanation, the absence of an interface between the first insulating spacer 142 and the second insulating spacer 162 is represented by a dotted line between the first insulating spacer 142 and the second insulating spacer 162. An interface may be formed between the first insulating spacer 142 and the contact insulation layer 130.

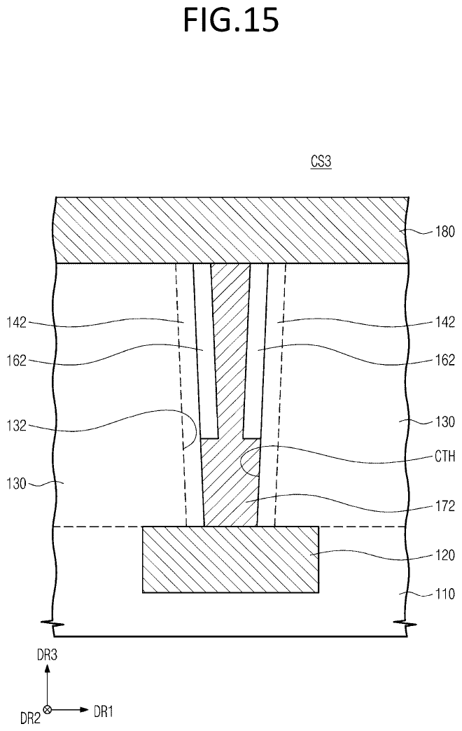

FIG. 15 is a cross-sectional view of a contact structure according to exemplary implementations. For the sake of brevity, differences from what was described with reference to FIG. 2 are described.

Referring to FIG. 15, a contact structure CS3 may be provided. Unlike what was described with reference to FIG. 2, the first insulating spacer 142 and the contact insulation layer 130 may constitute a single film. The first insulating spacer 142 and the contact insulation layer 130 may be connected to each other without an interface therebetween. For example, the first insulating spacer 142 and the contact insulation layer 130 may include substantially the same material. For convenience of explanation, the absence of an interface between the first insulating spacer 142 and the contact insulation layer 130 is represented by a dotted line between the first insulating spacer 142 and the contact insulation layer 130. An interface may be formed between the first insulating spacer 142 and the second insulating spacer 162.

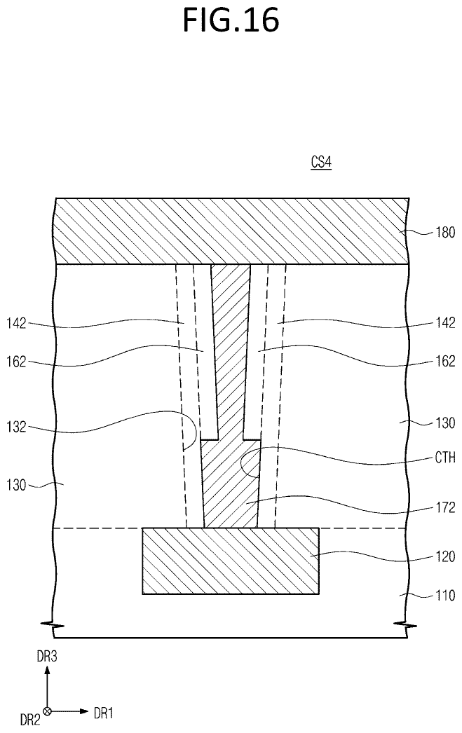

FIG. 16 is a cross-sectional view of a contact structure according to exemplary implementations. For the sake of brevity, differences from what was described with reference to FIG. 2 are described.

Referring to FIG. 16, a contact structure CS4 may be provided. Unlike what was described with reference to FIG. 2, the first insulating spacer 142 and the second insulating spacer 162 may constitute a single film. The first insulating spacer 142 and the second insulating spacer 162 may be connected to each other without an interface therebetween. The first insulating spacer 142 and the contact insulation layer 130 may constitute a single film. The first insulating spacer 142 and the contact insulation layer 130 may be connected to each other without an interface therebetween. For example, the first insulating spacer 142, the second insulating spacer 162, and the contact insulation layer 130 may include substantially the same material. For convenience of explanation, the absence of interfaces between the first insulating spacer 142 and the second insulating spacer 162 and between the first insulating spacer 142 and the contact insulation layer 130 is represented by dotted lines between the first insulating spacer 142 and the second insulating spacer 162 and between the first insulating spacer 142 and the contact insulation layer 130.

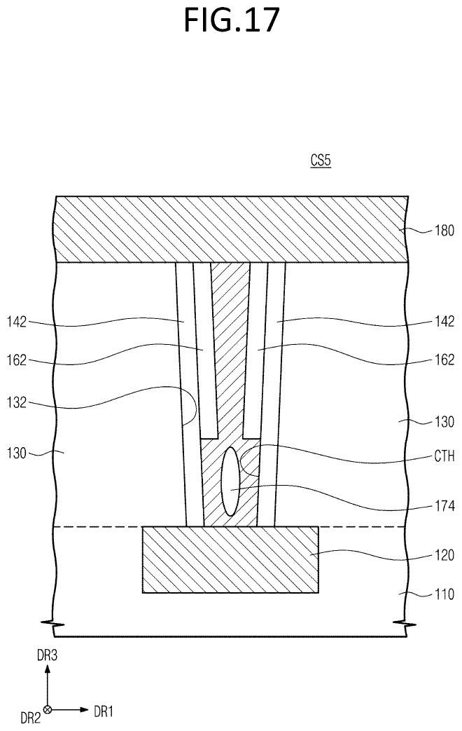

FIG. 17 is a cross-sectional view of a contact structure according to exemplary implementations. For the sake of brevity, differences from what was described with reference to FIG. 2 are described.

Referring to FIG. 17, a contact structure CS5 may be provided. Unlike what was described with reference to FIG. 2, a void 174 may be provided in the contact 172. For example, the void 174 may be formed depending on the process conditions for forming the contact 172. Exemplarily, a void 174 provided in the contact 172 between the second insulating spacer 162 and the first conductive line 120 is illustrated. In exemplary implementations, the void 174 may be formed in the contact 172 on the side of the second insulating spacer 162, or may be formed across the contact 172 between the second insulating spacer 162 and the first conductive line 120 and the contact 172 on the side of the second insulating spacer 162.

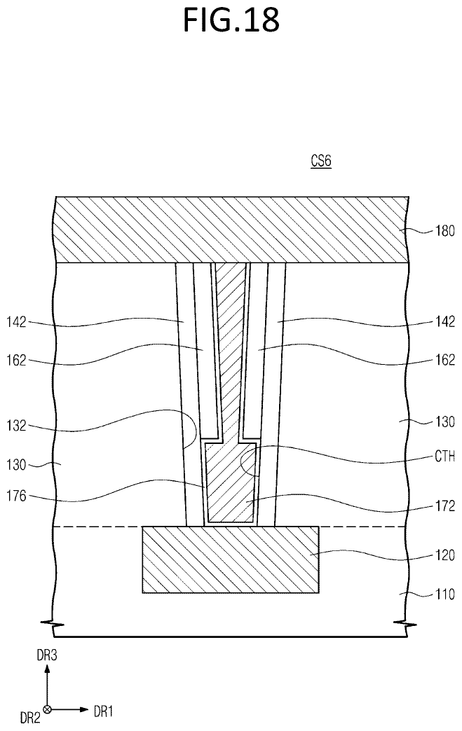

FIG. 18 is a cross-sectional view of a contact structure according to exemplary implementations. For the sake of brevity, differences from what was described with reference to FIG. 2 are described.

Referring to FIG. 18, a contact structure CS6 may be provided. Unlike what was described with reference to FIG. 2, the contact structure CS6 may further include a barrier film 176 extending along the surface of the contact 172. The barrier film 176 may be configured to protect other films (e.g., the first insulating spacer 142, the second insulating spacer 162, and the first conductive line 120) when forming the contact 172. For example, the barrier film 176 may include one of a titanium nitride film, a stack of a titanium film and a titanium nitride film, and a stack of a titanium film and a tungsten nitride film.

The barrier film 176 may be interposed between the contact 172 and the second insulating spacer 162. The barrier film 176 may be interposed between the contact 172 and the first insulating spacer 142. The barrier film 176 may be interposed between the contact 172 and the first conductive line 120. The barrier film 176 may expose the upper surface of the contact 172. For example, the upper surface of the contact 172 may directly contact the second conductive line 180.

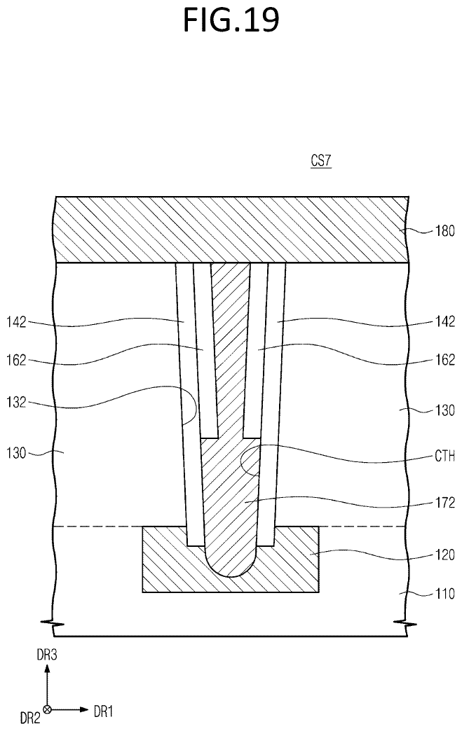

FIG. 19 is a cross-sectional view of a contact structure according to exemplary implementations. For the sake of brevity, differences from what was described with reference to FIG. 2 are described.

Referring to FIG. 19, a contact structure CS7 may be provided. Unlike what was described with reference to FIG. 2, the first insulating spacer 142 and the contact 172 may extend further beyond the top surface of the first conductive line 120 toward the bottom surface of the first conductive line 120 (in the direction opposite to the third direction DR3). The lower ends of the first insulating spacer 142 and the contact 172 may be located at a level between the top surface and the bottom surface of the first conductive line 120. The first insulating spacer 142 and the contact 172 may overlap with the upper portion of the first conductive line 120 along the first direction DR1. The side of the first insulating spacer 142 located opposite to the contact 172 and the bottom surface of the first insulating spacer 142 may contact the first conductive line 120.

The contact 172 may extend further toward the bottom surface of the first conductive line 120 than the first insulating spacer 142. The lower end of the contact 172 may be located at a level between the lower end of the first insulating spacer 142 and the bottom surface of the first conductive line 120. In exemplary implementations, the lower portion of the contact 172 may have a convex shape. The lower portion of the contact 172 may be electrically connected to the first conductive line 120. For example, the lower portion of the contact 172 may directly contact the first conductive line 120.

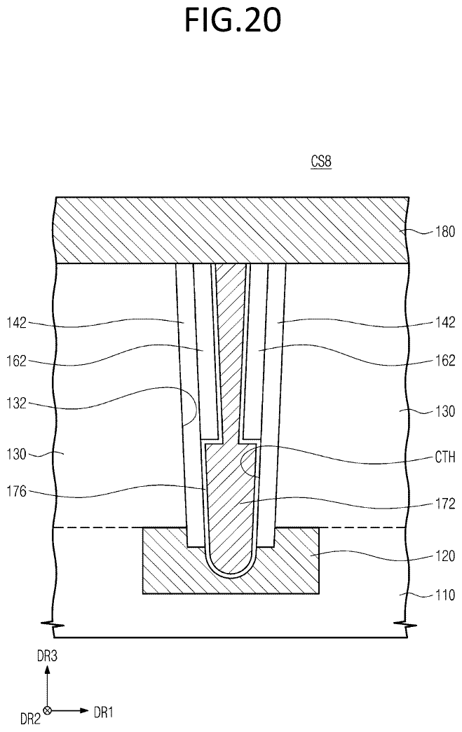

FIG. 20 is a cross-sectional view of a contact structure according to exemplary implementations. For the sake of brevity, differences from what was described with reference to FIG. 19 are described.

Referring to FIG. 20, a contact structure CS8 may be provided. Unlike what was described with reference to FIG. 19, the contact structure CS8 may further include a barrier film 176 extending along the surface of the contact 172. The barrier film 176 may be configured to protect other films (e.g., the first insulating spacer 142, the second insulating spacer 162, and the first conductive line 120) when forming the contact 172. For example, the barrier film 176 may include one of a titanium nitride film, a stack of a titanium film and a titanium nitride film, and a stack of a titanium film and a tungsten nitride film.

The barrier film 176 may be interposed between the contact 172 and the second insulating spacer 162. The barrier film 176 may be interposed between the contact 172 and the first insulating spacer 142. The barrier film 176 may be interposed between the contact 172 and the first conductive line 120. The barrier film 176 may expose the upper surface of the contact 172. For example, the upper surface of the contact 172 may directly contact the second conductive line 180.

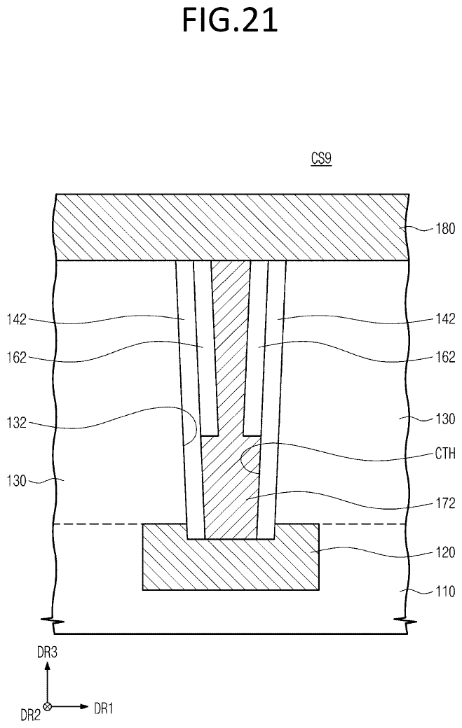

FIG. 21 is a cross-sectional view of a contact structure according to exemplary implementations. For the sake of brevity, differences from what was described with reference to FIG. 19 are described.

Referring to FIG. 21, a contact structure CS9 may be provided. Unlike what was described with reference to FIG. 19, the contact 172 may extend toward the bottom surface of the first conductive line 120 to substantially the same level as the first insulating spacer 142. The bottom surface of the contact 172 may be located at substantially the same level as the bottom surface of the first insulating spacer 142. For example, the bottom surface of the contact 172 and the bottom surface of the first insulating spacer 142 may be substantially coplanar.

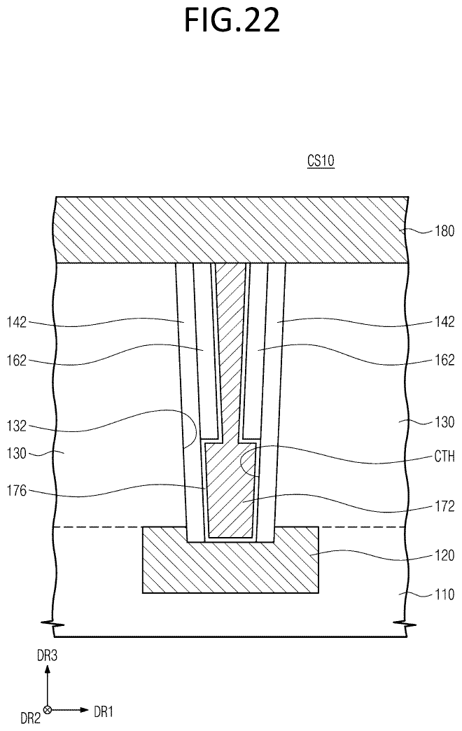

FIG. 22 is a cross-sectional view of a contact structure according to exemplary implementations. For the sake of brevity, differences from what was described with reference to FIG. 21 are described.

Referring to FIG. 22, a contact structure CS10 may be provided. Unlike what was described with reference to FIG. 21, the contact structure CS10 may further include a barrier film 176 extending along the surface of the contact 172. The barrier film 176 may be configured to protect other films (e.g., the first insulating spacer 142, the second insulating spacer 162, and the first conductive line 120) when forming the contact 172. For example, the barrier film 176 may include one of a titanium nitride film, a stack of a titanium film and a titanium nitride film, and a stack of a titanium film and a tungsten nitride film.

The barrier film 176 may be interposed between the contact 172 and the second insulating spacer 162. The barrier film 176 may be interposed between the contact 172 and the first insulating spacer 142. The barrier film 176 may be interposed between the contact 172 and the first conductive line 120. The barrier film 176 may expose the upper surface of the contact 172. For example, the upper surface of the contact 172 may directly contact the second conductive line 180.

According to the present disclosure, a contact structure with improved electrical characteristics may be provided.

According to the present disclosure, a semiconductor memory device with improved electrical characteristics may be provided.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A contact structure comprising:
a contact insulation layer defining a first hole;
a first insulating spacer along a side of the first hole;
a second insulating spacer on an upper portion of a side surface of the first insulating spacer; and
a contact disposed in a second hole defined by the first insulating spacer and the second insulating spacer,
wherein the contact comprises a first portion on a side surface of the first insulating spacer and a second portion on a side surface of the second insulating spacer, each of the first portion and the second portion has a width that changes in a direction from a bottom surface of the contact toward an upper surface of the contact, and
wherein a maximum width of the first portion is greater than a minimum width of the second portion.

2. The contact structure of claim 1, comprising:
a barrier film on a side surface of the contact and the bottom surface of the contact.

3. The contact structure of claim 2, wherein an upper surface of the contact is free of the barrier film.

4. The contact structure of claim 1, wherein the first insulating spacer and the second insulating spacer constitute a single film.

5. The contact structure of claim 1, wherein the contact insulation layer and the first insulating spacer constitute a single film.

6. The contact structure of claim 1, wherein a portion of the side surface of the first insulating spacer is free of the second insulating spacer.

7. The contact structure of claim 1, wherein a portion of a side surface of the contact is free of the second insulating spacer.

8. The contact structure of claim 1, wherein a lower portion of the contact has a convex shape.

9. The contact structure of claim 1, comprising:
a first conductive line electrically connected to the first portion of the contact; and
a second conductive line electrically connected to the second portion of the contact,
wherein a distance between a bottom surface of the first insulating spacer and a bottom surface of the first conductive line is less than a distance between a top surface of the first conductive line and the bottom surface of the first conductive line.

10. The contact structure of claim 9, wherein a distance between a lower end of the first portion of the contact and the bottom surface of the first conductive line is less than the distance between the bottom surface of the first insulating spacer and the bottom surface of the first conductive line.

11. The contact structure of claim 9, wherein the second insulating spacer is spaced apart from the first conductive line and contacts the second conductive line.

12. A contact structure comprising:
a first conductive line extending in a first direction;
a second conductive line extending in a second direction intersecting the first conductive line in the first direction; and
a contact between the first conductive line and the second conductive line,
wherein the contact includes a first portion adjacent to the first conductive line and a second portion adjacent to the second conductive line,
wherein each of the first portion and the second portion has a width that changes in a direction from the first conductive line toward the second conductive line, and
wherein a maximum width of the first portion is greater than a minimum width of the second portion.

13. The contact structure of claim 12, comprising:
a barrier film on a side surface and a bottom surface of the contact.

14. The contact structure of claim 12, wherein a lower end of the first portion of the contact has a convex shape.

15. The contact structure of claim 12, wherein a distance between the first portion of the contact and a bottom surface of the first conductive line is less than a distance between a top surface of the first conductive line and the bottom surface of the first conductive line.

16. The contact structure of claim 15, wherein the first conductive line has a side surface spaced apart from and facing a side surface of the contact.

17. A semiconductor memory device comprising:
a word line extending in a first direction;
a bit line extending in a second direction intersecting the word line extending in the first direction and spaced apart from the word line in a third direction;
a selector-only memory device between the word line and the bit line; and
a plurality of contacts electrically connected to the word line and the bit line,
wherein each of the plurality of contacts includes a first portion relatively far from the word line or the bit line and a second portion relatively close to the word line or the bit line,
wherein each of the first portion and the second portion has a width that changes along the third direction, and
wherein a maximum width of the first portion is greater than a minimum width of the second portion.

18. The semiconductor memory device of claim 17, comprising:
a barrier film on a side surface and a bottom surface of each of the plurality of contacts.

19. The semiconductor memory device of claim 17, comprising:
a plurality of conductive lines electrically connected to the word line and the bit line, respectively, through the plurality of contacts,
wherein a distance between a lower end of a first portion of each contact and a bottom surface of a respective conductive line is less than a distance between a top surface of the respective conductive line and the bottom surface of the respective conductive line.

20. The semiconductor memory device of claim 17, comprising:
a plurality of conductive lines electrically connected to the word line and the bit line, respectively, through the plurality of contacts,
wherein a respective conductive line has a side surface spaced apart from and facing a side surface of the corresponding contact.
